(19) United States
(12) Patent Application Publication
(10) Pub. No.: US 2015/0214398 A1
(43) Pub. Date: Jul. 30, 2015

(54) PHOTOVOLTAIC ELEMENT AND MANUFACTURING METHOD THEREOF

(71) Applicant: Mitsubishi Electric Corporation, Tokyo (JP)

(72) Inventors: Tatsuro Watahiki, Tokyo (JP); Shuichi Hiza, Tokyo (JP); Takehiko Sato, Tokyo (JP)

(73) Assignee: Mitsubishi Electric Corporation, Tokyo (JP)

(21) Appl. No.: 14/420,512

(22) PCT Filed: Aug. 27, 2013
(86) PCT No.: PCT/JP2013/072899

§ 371 Date: Feb. 9, 2015

(30) Foreign Application Priority Data
Aug. 29, 2012 (JP) 2012-189220

(51) Int. Cl. H01L 31/0224; H01L 31/0376; H01L 31/18; H01L 31/077

(52) U.S. Cl. CPC H01L 31/022475; H01L 31/077; H01L 31/03762; H01L 31/1884; H01L 31/1804

(57) ABSTRACT

A first amorphous silicon i layer and an amorphous silicon p layer are provided on a first main surface, side surfaces, and a peripheral portion of a second main surface of an n-type silicon substrate. A first ITO layer is provided over the first main surface and the side surfaces, a second amorphous silicon i layer and an amorphous silicon n layer are provided on the second main surface, and a second ITO layer having a smaller area than the n-type silicon substrate is provided thereon excluding the peripheral portion. On the peripheral portion of the second main surface, a structure, in which the first amorphous silicon i layer, the amorphous silicon p layer, the second amorphous silicon i layer, and the amorphous silicon n layer are laminated in this order, is provided.

### FIELD

The present invention relates to a photovoltaic element and a manufacturing method thereof, and particularly relates to a heterojunction photovoltaic element configured by combining an amorphous semiconductor layer and a crystalline semiconductor substrate and a manufacturing method thereof.

### BACKGROUND

Crystalline solar cells using a crystalline semiconductor substrate have a high photoelectric conversion efficiency. In particular, crystalline silicon solar cells using a crystalline silicon substrate have already been widely put into practical use. Specially, as a heterojunction solar cell using an amorphous or microcrystalline semiconductor thin film for a conductive thin film, a solar cell that has an intrinsic semiconductor thin film between the conductive thin film and the crystalline substrate has been developed. In this solar cell, the intrinsic semiconductor film between the crystalline surface and the conductive thin film has a function of passivating defects on the surface and preventing loss due to diffusion of impurities from the conductive thin film and recombination of carriers; therefore, this solar cell can obtain a high open circuit voltage and thus has a high photoelectric conversion efficiency.

In such a solar cell, in order to improve the characteristics, it is necessary to increase the short circuit current and the fill factor while maintaining a high open circuit voltage. In order to increase the short circuit current, it is important to increase the optically and electrically effective incident surface as much as possible so that more light is absorbed. Moreover, it is important for the fill factor to increase the parallel resistance sufficiently while reducing the series resistance as much as possible over the whole region of the element. To that end, it is important that a transparent conductive film is arranged such that the series resistance is electrically sufficiently low.

In order to realize this ideal state, it is necessary to cover the whole surface of the substrate with a passivation film to passivate defects, then cover the whole surface of the light receiving surface (incident surface) of the substrate with, as an emitter layer, a semiconductor layer having a conductivity type different from that of the substrate, and then cover the whole surface of the emitter layer formed on the incident surface of the substrate with a transparent conductive film. At the same time, it is necessary to cover the back surface with a semiconductor layer having the same conductivity type as that of the substrate and cover the semiconductor layer with an electrode.

However, in reality, with CVD methods that have been used for manufacturing semiconductor layers, a film is, in some cases, deposited such that it wraps around the side surfaces or the opposite surface of the substrate, which are surfaces other than the deposition target surface. This may result in the failure of the formation of a junction as designed near the end portion of the substrate and therefore a reduction in characteristics due to the failure in collecting carriers may be caused. Moreover, even when a conventional sputtering method is used as a deposition method of a transparent conductive film, a film is deposited on the main surface and is also deposited such that it wraps around the side surfaces. Consequently, positive and negative electrodes are short-circuited at the side surfaces, the end portion of the deposition target surface, or the end portion of the opposite surface; therefore, the characteristics easily degrade.

A technology is disclosed in Patent Literature 1 in which an intrinsic amorphous semiconductor, a second-conductivity-type amorphous semiconductor layer, and a conductive thin film are deposited such that they wrap around from the first main surface to the side surfaces of the crystalline semiconductor substrate, an intrinsic amorphous semiconductor, a first-conductivity-type amorphous semiconductor, and a conductive thin film are deposited such that they wrap around the second main surface and the side surfaces, and thereafter, positive and negative electrodes are separated from each other by forming grooves on any of the main surfaces with a laser or the like, thereby maintaining a maximum effective region of the passivation film while preventing leakage.

However, when grooves are formed on the surface on which a junction is formed with a different conductivity type, although leakage can be prevented, carriers cannot be collected in the region outside the formed grooves and thus the effective area is reduced. Moreover, when grooves are formed on the surface on which a junction is formed with the same conductivity type, positive and negative electrodes are short-circuited through the substrate and thus leakage current cannot be ignored. Consequently, degradation of the characteristics is significant. In either case, an additional process for forming the grooves is necessary and the process becomes complicated because of the formation of the grooves on the passivation film and the conductive film.

A configuration is disclosed in Patent Literature 2 in which an intrinsic semiconductor layer and a conductivity-type semiconductor layer are deposited on the back surface side of a crystalline semiconductor substrate, in the order that they appear in this sentence, by using a mask such that they have a smaller area than that of the substrate, thereby preventing leakage at the end portion of the substrate. Additionally, a technology is disclosed in which an intrinsic semiconductor layer is first deposited on the whole surface of the substrate and then a conductivity-type semiconductor layer is deposited, thereby passivating the whole surface.

However, with the method of depositing an intrinsic semiconductor layer with a smaller area than that of the substrate, there is no intrinsic semiconductor layer on part of the back surface and thus the surface thereof cannot be passivated; therefore, generated carriers are recombined and thus the characteristics are significantly degraded. Moreover, with the method of first depositing an intrinsic semiconductor layer on the whole surface of the substrate, although a passivation film is formed on the whole surface of the substrate, there is no method of preventing leakage at the end portion due to the transparent conductive film formed on the passivation film, which leads to a reduction in the open circuit voltage and the short circuit current.

A technology is disclosed in Patent Literature 3 in which after a first-conductivity-type amorphous silicon layer and an electrode layer are deposited on the first main surface of a single-crystal silicon substrate, a contact prevention layer is formed to prevent leakage, and then a second-conductivity-type amorphous silicon layer and an electrode layer are formed on the second main surface.

However, it is necessary to perform an additional process for forming the contact prevention layer that prevents leakage and the process of forming a thick dielectric layer only on the side surfaces has poor production characteristics and is not easy to perform. Moreover, it is necessary to form an electrode layer on the first main surface before an amorphous semiconductor layer is formed on the second main surface and, at this point, the electrode layer often comes into contact with the surface of the substrate on which the passivation film is not present because the electrode layer wraps around the end portion of the second main surface, which leads to a reduction in the effective area and degradation of the characteristics, such as a reduction in the open circuit voltage.

### CITATION LIST

### Patent Literature

Patent Literature 1: Japanese Patent No. 3349308

Patent Literature 2: Japanese Patent No. 3825585

Patent Literature 3: Japanese Patent Application Laid-open No. 2011-60971

### SUMMARY

### Technical Problem

However, with the above conventional technologies, it is necessary to perform an additional complicated process to prevent leakage current or to limit the effective area such that it is smaller than the substrate to prevent leakage current; therefore, there is a problem in that efficiency is reduced.

The present invention has been achieved in view of the above and an object of the present invention is to obtain a photovoltaic element that does not need an additional new process, that has a high efficiency because the entire main surface on the light receiving surface side of the substrate and the entire side surfaces of the substrate are an effective area, and that is capable of preventing leakage current, and a manufacturing method thereof.

### Solution to Problem

In order to solve the above problems and achieve the object, a photovoltaic element according to the present invention including: a first-conductivity-type semiconductor substrate that includes a first main surface, a side surface, and a second main surface; a second-conductivity-type semiconductor layer that is formed such that the second-conductivity-type semiconductor layer entirely covers the first main surface of the semiconductor substrate and covers a peripheral portion of the second main surface by wrapping around the side surface from the first main surface; a first intrinsic semiconductor layer that is interposed between the second-conductivity-type semiconductor layer and the semiconductor substrate; a first transparent conductive film that is formed such that the first transparent conductive film is in contact with the second-conductivity-type semiconductor layer and extends to the side surface from the first main surface; a first-conductivity-type semiconductor layer that is formed over the second main surface of the semiconductor substrate; a second intrinsic semiconductor layer that is interposed between the first-conductivity-type semiconductor layer and the semiconductor substrate; and a second transparent conductive film that is provided over a second main surface of the semiconductor substrate such that the second transparent conductive film is in contact with the first-conductivity-type semiconductor layer, wherein the second transparent conductive film is formed such that an end portion is located on an inner side of an outer edge of a second main surface of the semiconductor substrate, the second transparent conductive film is formed such that the second transparent conductive film does not intersect with the first transparent conductive film along a normal line that extends from the end portion of the second transparent conductive film toward a surface of the semiconductor substrate, and on the second main surface and between an end portion of the first transparent conductive film and the end portion of the second transparent conductive film, either a structure, in which the first intrinsic semiconductor layer, the second-conductivity-type semiconductor layer, the second intrinsic semiconductor layer, and the first-conductivity-type semiconductor layer are laminated in order, or a structure, in which the first intrinsic semiconductor layer, the second-conductivity-type semiconductor layer, and the first-conductivity-type semiconductor layer are laminated in order, is provided.

### Advantageous Effects of Invention

According to the present invention, a substantially intrinsic semiconductor layer (intrinsic semiconductor layer) and a semiconductor thin film having a conductivity type different from that of the semiconductor substrate are provided on the first main surface, the side surfaces, and the peripheral portion of the second main surface of the semiconductor substrate, a first transparent conductive film is provided over the first main surface and the side surfaces, an intrinsic semiconductor layer and a semiconductor layer having the same conductivity type as that of the semiconductor substrate are provided on the second main surface, and a second transparent conductive film having a smaller area than that of the semiconductor substrate is provided on the semiconductor substrate. On the second main surface, between the end portion of the first transparent conductive film and the end portion of the second transparent conductive film, the intrinsic semiconductor, the semiconductor thin film having a conductivity type different from that of the semiconductor substrate, the intrinsic semiconductor layer, and the semiconductor layer having the same conductivity type as that of the semiconductor substrate are provided in the order that they appear in this sentence, thereby suppressing leakage current between the semiconductor substrate and the first transparent conductive film at the end portion of the semiconductor substrate. Furthermore, in the space between the first and second transparent conductive films and on the end portion, the films are laminated in the same order so as to form a pin junction or a pn junction; therefore, the forward current flows effectively through the junction between the films and the substrate and the reverse current flowing in the surface and the interface of the semiconductor thin film and the end surface of the semiconductor thin film is blocked, whereby the flow of the charge is maintained in a normal state. Consequently, the function of an electrical cell is exhibited by exhibiting the current collecting effect and leakage current is suppressed. With such a configuration, the optically and electrically effective area can be maximized only by controlling the end portion of each layer and leakage current can be prevented not only between the first and second transparent conductive films but also between the semiconductor substrate and the first transparent conductive film without requiring the addition of a new film or an additional complex process.

### BRIEF DESCRIPTION OF DRAWINGS

FIG. 1 is a cross-sectional view of a photovoltaic element according to a first embodiment of the present invention.

FIG. 2 is a diagram illustrating the manufacturing process of the photovoltaic element according to the first embodiment of the present invention, where (a) to (c) are process cross-sectional views.

FIG. 3 is a schematic cross-sectional view of a CVD device in manufacturing the photovoltaic element according to the first embodiment of the present invention, where (a) is a schematic cross-sectional view of a CVD device used for forming a second-conductivity-type semiconductor layer and (b) is a schematic cross-sectional view of a CVD device used for forming a first-conductivity-type semiconductor layer.

FIG. 4 is a flowchart illustrating the manufacturing process of the photovoltaic element according to the first embodiment of the present invention.

FIG. 5 is a comparative diagram illustrating the output characteristics of the photovoltaic element according to the first embodiment of the present invention and a comparative example.

FIG. 6 is a cross-sectional view of a photovoltaic element according to a second embodiment in the present invention.

FIG. 7 is a flowchart illustrating the manufacturing process of the photovoltaic element according to the second embodiment in the present invention.

FIG. 8 is a cross-sectional view of a photovoltaic element according to a third embodiment in the present invention.

FIG. 9 is a flowchart illustrating the manufacturing process of the photovoltaic element according to the third embodiment in the present invention.

FIG. 10 is a cross-sectional view of a photovoltaic element according to a fourth embodiment in the present invention.

FIG. 11 is a flowchart illustrating the manufacturing process of the photovoltaic element according to the fourth embodiment in the present invention.

FIG. 12 is a cross-sectional view of a photovoltaic element according to a comparison example.

FIG. 13 is a cross-sectional view of a photovoltaic element according to a fifth embodiment in the present invention.

FIG. 14 is a flowchart illustrating the manufacturing process of the photovoltaic element according to the fifth embodiment in the present invention.

FIG. 15 is a flowchart illustrating the second manufacturing process of the photovoltaic element according to the fifth embodiment in the present invention.

### DESCRIPTION OF EMBODIMENTS

Exemplary embodiments of a photovoltaic element and a manufacturing method thereof according to the present invention will be explained below in detail with reference to the drawings. This invention is not limited to the embodiments and can be modified as appropriate without departing from the scope of the invention. In the drawings illustrated below, for easier understanding, scales of respective layers or respective members may be shown differently from what they are in reality. This also holds true for the relationships between the drawings.

### First Embodiment

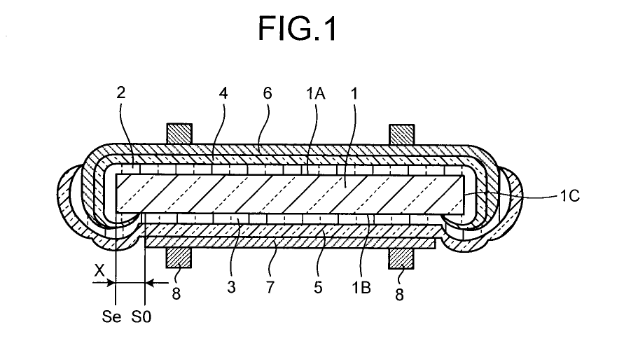

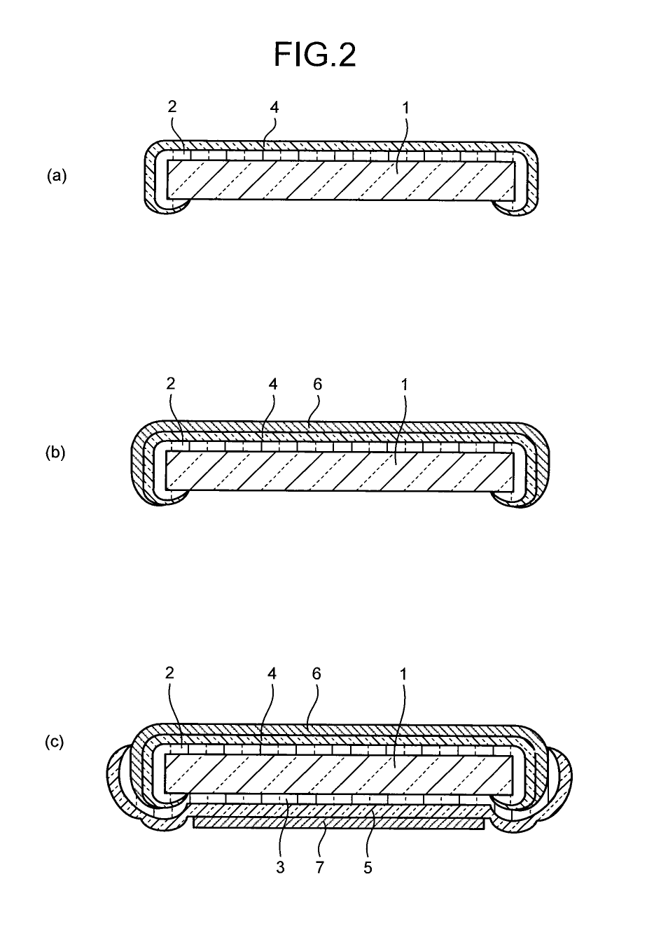

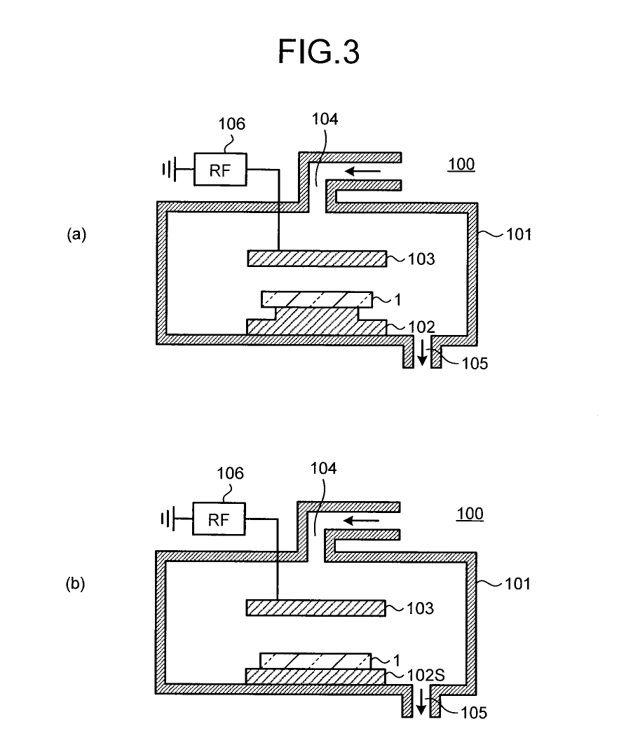

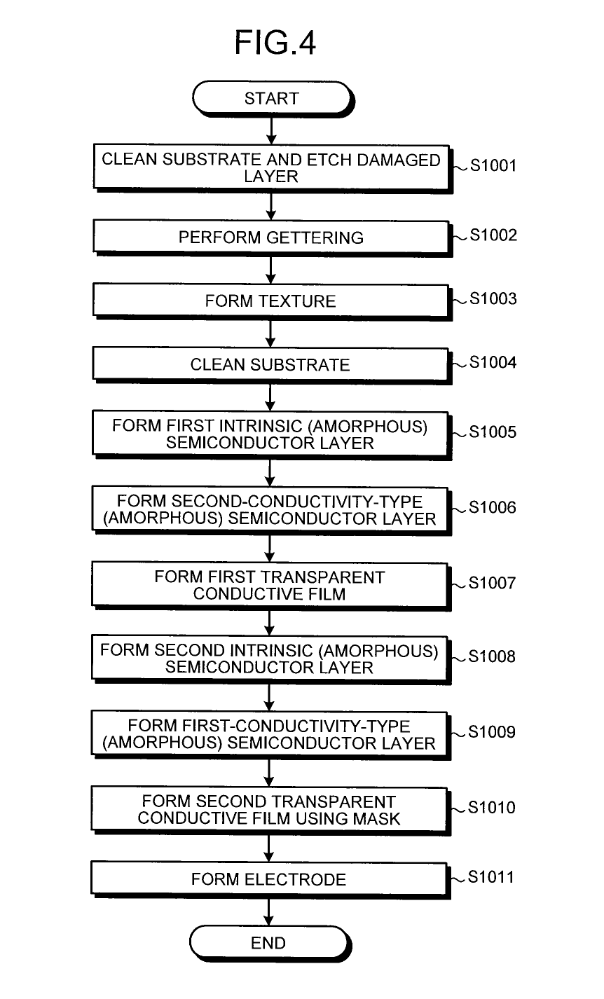

FIG. 1 is a cross-sectional view of a photovoltaic element according to the present embodiment. FIG. 2 is a diagram illustrating the manufacturing process of the photovoltaic element, where (a) to (c) are process cross-sectional views. FIG. 3 is a schematic diagram illustrating a substrate arrangement for controlling the deposition area of the substrate in a device for manufacturing the photovoltaic element, where (a) is a schematic cross-sectional view of a CVD device used for forming a second-conductivity-type semiconductor layer and (b) is a schematic cross-sectional view of a CVD device used for forming a first-conductivity-type semiconductor layer. FIG. 4 is a flowchart illustrating the manufacturing process of the photovoltaic element according to a first embodiment of the present invention.

In the photovoltaic element in the first embodiment, a second-conductivity-type semiconductor layer is formed such that it covers the entire first main surface of the semiconductor substrate and covers a predetermined width of the peripheral portion of the second main surface of the semiconductor substrate by wrapping around the side surfaces of the semiconductor substrate, with a first intrinsic semiconductor layer therebetween. A first-conductivity-type semiconductor layer is formed over the second main surface of the semiconductor substrate with a second intrinsic semiconductor layer therebetween. The photovoltaic element in the first embodiment further includes a first transparent conductive film, which is formed such that it is in contact with the second-conductivity-type semiconductor layer and extends to the side surfaces from the first main surface, and a second transparent conductive film, which is provided such that it is in contact with the first-conductivity-type semiconductor layer. Furthermore, the second transparent conductive film is formed such that its end portion is located on the inner side of the outer edge of the second main surface of the semiconductor substrate and it does not intersect with the first transparent conductive film along the normal line that extends from the end portion of the second transparent conductive film toward the surface of the semiconductor substrate. Moreover, on the second main surface, the photovoltaic element in the first embodiment includes a structure in which the first intrinsic semiconductor layer, the second-conductivity-type semiconductor layer, the second intrinsic semiconductor layer, and the first-conductivity-type semiconductor layer are laminated, in the order that they appear in this sentence, between the end portion of the first transparent conductive film and the end portion of the second transparent conductive film. In other words, even in the end portion of the second main surface of the semiconductor substrate, the films are laminated in the same order so as to form a pin junction; therefore, the forward current flows effectively through the junction between the films and the substrate and the reverse current flowing in the surface and the interface of the semiconductor thin film and the end surface of the semiconductor thin film can be blocked, whereby the flow of the charge is maintained in a normal state. Consequently, leakage current is suppressed and the function of an electrical cell is exhibited by exhibiting the current collecting effect.

The second transparent conductive film is formed such that its outer edge is located on the inner side of the outer edge of the second main surface of the semiconductor substrate by a predetermined distance and is formed such that it does not intersect with the first transparent conductive film along the normal line that extends from the outer edge of the second transparent conductive film toward the surface of the semiconductor substrate. In a similar manner, the structure in which the first intrinsic semiconductor layer, the second-conductivity-type semiconductor layer, the second intrinsic semiconductor layer, the first-conductivity-type semiconductor layer are laminated, in the order that they appear in this sentence, is also formed such that it extends to the inner side of the outer edge of the second main surface by a predetermined distance.

In this example, an n-type single-crystal silicon substrate (hereinafter, referred to as an n-type silicon substrate in some cases) 1, which includes a first main surface 1A, side surfaces 1C, and a second main surface 1B and has a thickness between 100 μm and 500 μm, is used as the first-conductivity-type semiconductor substrate. A first amorphous silicon i layer 2 is used as the first intrinsic semiconductor layer and a second amorphous silicon i layer 3 is used as the second intrinsic semiconductor layer. An amorphous silicon p layer 4 is used as the second-conductivity-type semiconductor layer and an amorphous silicon n layer 5 is used as the first-conductivity-type semiconductor layer. A first ITO (Indium Tin Oxide) layer 6 is used as the first transparent conductive film and a second ITO (Indium Tin Oxide) layer 7 is used as the second transparent conductive film. A metal electrode 8 is used for current collection.

Specifically, in the photovoltaic element in the first embodiment, as illustrated in FIG. 1, the amorphous silicon p layer 4 is formed such that it covers the entire first main surface 1A of the n-type silicon substrate 1 and extends to a predetermined width of the peripheral portion of the second main surface 1B by wrapping around the side surfaces 10, with the first amorphous silicon i layer 2 therebetween. The first ITO layer 6 is formed such that it is in contact with the amorphous silicon p layer 4 and extends to the side surfaces 10 from the first main surface 1A. On the second main surface 1B of the n-type silicon substrate 1, the amorphous silicon n layer 5 is formed with the second amorphous silicon i layer 3 therebetween. The second ITO layer 7 is formed on the amorphous silicon n layer 5. The normal line S0, which extends from the end portion of the second ITO layer 7 toward the surface of the n-type silicon substrate 1, is formed such that it is located on the inner side of an end portion Se of the first ITO layer 6 on the second main surface 1B of the n-type silicon substrate 1 by a predetermined distance X. The distance (interval) X between the end portion of the first transparent conductive film and the end portion of the second transparent conductive film in the plane direction is equal to or more than 0.1 mm and equal to or less than 3 mm. Furthermore, on the second main surface 1B, the structure in which the first intrinsic semiconductor layer, the second-conductivity-type semiconductor layer, the second intrinsic semiconductor layer, and the first-conductivity-type semiconductor layer are laminated, in the order that they appear in this sentence, has a length equal to or more than 0.1 mm and equal to or less than 3 mm in the plane direction from the end portion Se.

The first ITO layer 6 extends up to substantially the outer edge of the n-type silicon substrate 1 and does not intersect with the first ITO layer 6 along the normal line S0, which extends from the first ITO layer 6 toward the surface of the n-type silicon substrate 1. The end portion Se of the first ITO layer 6 matches the outer edge of the n-type silicon substrate 1 and the outer edge of the second ITO layer 7 is formed such that it is located on the inner side of the outer edge of the n-type silicon substrate 1 by a predetermined distance X. The second ITO layer 7 is formed such that it does not intersect with the first ITO layer 6 along the normal line S0, which extends from the outer edge of the second ITO layer 7 toward the surface of the n-type silicon substrate 1.

The amorphous silicon n layer 5, which has the same conductivity type as that of the n-type silicon substrate 1, is formed over the amorphous silicon p layer 4, which has a conductivity type different from that of the n-type silicon substrate 1.

Next, the manufacturing method of the photovoltaic element in the first embodiment will be explained in accordance with the flowchart of FIG. 4. An n-type single-crystal silicon substrate, i.e., the n-type silicon substrate 1, is used as a processing target substrate. Normally, a processing target substrate is obtained by slicing an ingot that is obtained by pulling; therefore, there is a risk that a native oxide film forms on the surface, structural defects are generated, and contamination by metals or the like occurs. Thus, the n-type silicon substrate 1 used in this example is cleaned and the damaged layer of the n-type silicon substrate 1 is etched (S1001).

After the n-type silicon substrate 1 is cleaned and the damaged layer of the n-type silicon substrate 1 is etched, a gettering process is performed to remove impurities in the n-type silicon substrate 1 (S1002). In the gettering process, impurities are segregated in a phosphorus glass layer that is formed by thermally diffusing phosphorus at a processing temperature of approximately 1000° C. and the phosphorus glass layer is then etched by using hydrogen fluoride or the like.

After the gettering process, a texture is formed on the substrate surface by performing wet etching using an alkaline solution and an additive in order to reduce the light reflection loss on the substrate surface (S1003). Potassium hydroxide, sodium hydroxide, or the like is used as the alkaline solution and isopropyl alcohol or the like is used as the additive. From FIG. 1 to FIG. 3, for ease of understanding of the configuration of the present embodiment, the concave and convex shape is not illustrated and the substrate surface is illustrated as a flat surface.

After the texture is formed, the n-type single-crystal silicon substrate 1 is cleaned so as to remove particles on the surface thereof, which is to be a heterojunction interface, and to eliminate organic contamination and metal contamination (S1004). For cleaning, for example, cleaning known as RCA cleaning, SPM cleaning (sulfuric acid-hydrogen peroxide mixture cleaning), HPM cleaning (hydrochloric acid-hydrogen peroxide mixture cleaning), DHF cleaning (dilute hydrofluoric acid cleaning), and alcohol cleaning are used.

The RCA cleaning is a method as follows: First, a wafer is immersed into a dilute hydrofluoric acid solution (HF) to elute a thin silicon oxide film on the surface. At this point, at the same time as the elution of the silicon oxide film, a lot of foreign matter adhered to the silicon oxide film is also removed. Furthermore, organic materials and particles are removed by using ammonia (NH₄OH)+hydrogen peroxide (H₂O₂). Next, metals are removed by using hydrochloric acid (HCl)+hydrogen peroxide (H₂O₂). Finally, finishing is performed by using ultra-pure water.

After the substrate is cleaned by using any of the above cleaning methods, semiconductor layers of respective conductivity types are formed in order on the n-type silicon substrate 1 so as to form a heterojunction and pn and nn⁺ junctions. The n-type silicon substrate 1 obtained after being subjected to the texture forming process and the cleaning process has a thickness between 100 μm and 500 μm.

First, as illustrated in FIG. 2(a), the first amorphous silicon i layer 2 having a thickness between approximately 1 nm and 10 nm and the amorphous silicon p layer 4 having a thickness between approximately 5 nm and 50 nm are deposited, in the order that they appear in this sentence, by using a plasma CVD method such that they cover the entire first main surface 1A of the n-type silicon substrate 1 and extend from the first main surface 1A to the side surfaces 1C and the peripheral portion of the second main surface 1B (S1005: first intrinsic amorphous semiconductor layer formation and S1006: second-conductivity-type amorphous semiconductor layer formation). The first amorphous silicon i layer 2 and the amorphous silicon p layer 4 are both amorphous; however, microcrystalline silicon may be used for both of them.

At this point, in order to deposit predetermined amorphous silicon layers not only on the first main surface 1A and the side surfaces 1C but also on the peripheral portion of the second main surface 1B, a plasma CVD device having a structure as illustrated in FIG. 3(a) is used. With a plasma CVD method, when the films are deposited on the first main surface 1A, the films are deposited such that the deposition area wraps around the other surfaces because the material gas flows around to the other surfaces. Therefore, by simply using a convex structure that has a convex portion having a smaller area than that of the n-type silicon substrate 1, which is a processing target substrate, as a support 102, it becomes possible to control the film deposition distance from the end portion Se of the second main surface 1B.

A plasma CVD device 100 used in this example includes a processing chamber 101 as illustrated in the schematic diagrams in FIGS. 3(a) and (b). The processing chamber 101 is a space that is surrounded by a chamber wall and in which a vacuum can be drawn. A gas supply portion 104, from which an impurity-containing process gas is supplied into the processing chamber 101, and a discharge portion 105 are formed on the chamber wall. In the processing chamber 101, the support 102, which serves also as an anode electrode, and a cathode electrode 103 are arranged facing each other. A plurality of openings (not illustrated) are formed in the cathode electrode 103, for example, such that they resemble a shower head. The cathode electrode 103 is electrically connected to a high-frequency (RF) power supply 106. The support 102, which also serves as an anode electrode, is electrically connected to, for example, a ground potential. The processing chamber 101 is connected to a discharge system (not illustrated), such as a vacuum pump, and to a pressure gauge (not illustrated) for the inside of the processing chamber through the discharge portion 105.

In the plasma CVD device 100, which is a semiconductor depositing device, after a vacuum is drawn in the processing chamber 101 by a vacuum pump through the discharge port 105, the n-type silicon substrate 1, which is a processing target substrate, is arranged on the support 102, which serves also as an anode electrode, by using a carrying mechanism (not illustrated). At this point, the first main surface 1A out of the two main surfaces (the first main surface 1A, which is a front surface, and the second main surface 1B, which is a back surface) of the n-type silicon substrate 1 supported by the support 102 faces the cathode electrode 103 side. Then, a process gas is supplied from the gas supply source (not illustrated) to the space between the support 102, which is used also as an anode electrode, and the cathode electrode 103 through the openings (not illustrated), which are formed in the cathode electrode 103 such that they resemble a shower head, via a mass flow controller (not illustrated) as a process-gas control system and the gas supply portion 104. A high-frequency power (high-frequency bias) supplied from the high-frequency power supply 106 is applied to the cathode electrode 103 and plasma of the process gas is generated in the space between the cathode electrode 103 and the support 102, which is used also as an anode electrode. The chemically active species generated in the plasma serve as a deposition precursor and react on the first main surface 1A of the n-type silicon substrate 1, thereby forming a desired film. At this point, on the n-type silicon substrate 1 that is placed on the support 102 that has a flat convex portion having a smaller area than that of the second main surface 1B, the deposition precursor flows from the first main surface 1A to the peripheral portion of the second main surface 1B around the side surfaces 1C to deposit the first amorphous silicon i layer 2 and the amorphous silicon p layer 4 in the order that they appear in this sentence.

Next, as illustrated in FIG. 2(b), in the second process, the first ITO layer 6 is formed as a transparent conductive film over the entire first main surface 1A of the n-type silicon substrate 1 on which the first amorphous silicon i layer 2 and the amorphous silicon p layer 4 are formed (S1007: first transparent conductive film formation). A sputtering method or a CVD method is used for forming the first ITO layer 6. Examples of the material of the transparent conductive film include indium oxide, zinc oxide, and SnO₂ in addition to ITO; however, the material of the transparent conductive film is not limited to these materials. FIG. 3(b) illustrates a cross-sectional view of the plasma CVD device when the first ITO layer 6 is formed. The n-type silicon substrate 1 is placed on a support 102S configured to have a flat stage as illustrated in FIG. 3(b); therefore, the first ITO layer 6 can be formed over the entire first main surface 1A and the side surfaces 10. At this point, the first ITO layer 6 is formed over the first main surface 1A and the side surfaces 10 and also, depending on the deposition conditions, wraps around the peripheral portion of the second main surface 1B. The support mechanism illustrated in FIG. 3(a) can be manufactured such that the distance with which the first ITO layer 6 wraps around the second main surface 1B is sufficiently smaller than the distance with which the first amorphous silicon i layer 2 and the amorphous silicon p layer 4 formed in the first process illustrated in FIG. 1 wrap around onto the second main surface 1B. At this point, even when the first ITO layer 6 is formed by a sputtering method, a desired cross-sectional shape can be obtained by using a support having the same shape for supporting the n-type silicon substrate 1.

Next, as illustrated in FIG. 2(c), in the third process, the intrinsic amorphous silicon layer (second amorphous silicon i layer) 3 having a thickness between approximately 1 nm and 10 nm and the n-type amorphous silicon layer (amorphous silicon n layer) 5 having a thickness between approximately 5 nm and 50 nm are deposited, in the order that they appear in this sentence, on the entire second main surface 1B by a plasma CVD method (S1008: second intrinsic amorphous semiconductor layer formation and S1009: first-conductivity-type amorphous semiconductor layer formation). At this point, the intrinsic amorphous silicon layer and the n-type amorphous silicon layer are formed by using a CVD device having the structure illustrated in FIG. 3(b). The second amorphous silicon i layer 3 and the amorphous silicon n layer 5 are both amorphous; however, microcrystalline silicon may be used for both of them.

Thereafter, a transparent conductive film (the second ITO layer 7) is formed over the second main surface 1B by using a mask such that it has a smaller area than that of the substrate (S1010: second transparent conductive film formation). Finally, the metal electrode 8 is formed over the first main surface 1A and the second main surface 1B (S1011: electrode formation).

As described above, according to the photovoltaic element in the present embodiment, the effective area can be maximized while preventing leakage current; whereby the characteristics can be improved. The leakage current flowing between the ITOs through each amorphous layer can be suppressed by controlling the distance between the first ITO layer 6 and the second ITO layer 7. Furthermore, the structure in which the first amorphous silicon i layer 2, the amorphous silicon p layer 4, the second amorphous silicon i layer 3, and the amorphous silicon n layer 5 are laminated, in the order that they appear in this sentence, is provided between the first ITO layer 6 and the second ITO layer 7; therefore, the leakage current flowing between the first ITO layer 6 and the n-type silicon substrate 1 through each amorphous layer can be suppressed. In addition to this, on the end portion of the second main surface 1B of the n-type silicon substrate 1, the order of the films is maintained to form a pin junction; therefore, the flow of the charge is maintained in a normal state, thereby exhibiting the function of an electrical cell. Consequently, even on the end portion, although the second ITO layer 7 is withdrawn by the distance X from the end portion of the n-type silicon substrate 1, charge flows between the second ITO layer 7 and the first ITO layer 6; therefore, the current collecting effect is exhibited and this region serves as an electrical cell area. Moreover, the optically and electrically effective area can be maximized only by controlling the end portion of each layer and leakage current can be prevented not only between the first and second ITO layers 6 and 7 but also between the n-type silicon substrate 1 and the first ITO layer 6 without requiring the addition of a new film or an additional new complex process. In contrast, when a contact prevention layer is provided as in Patent Literature 3, the contact prevention layer is required to keep the thickness in order to exhibit its function, which causes a reduction in the effective electrical cell area. Moreover, a reduction in the open circuit voltage due to wrap-around is inevitable.

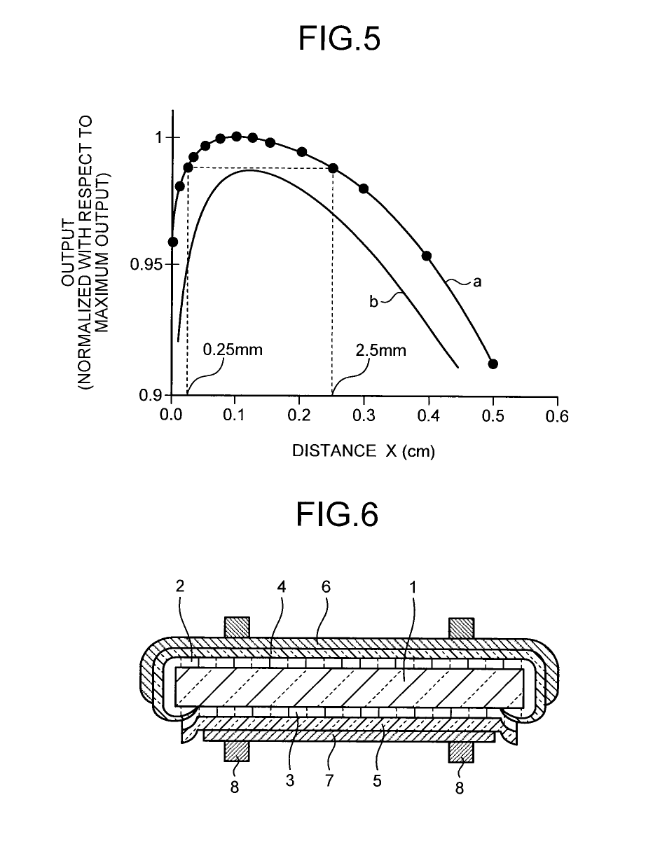

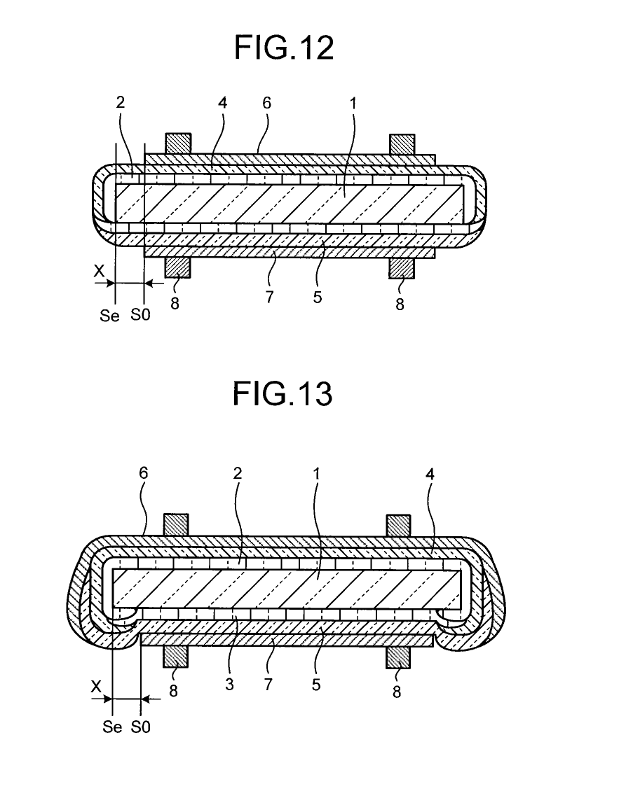

In FIG. 5, a graph illustrates with the curve “a” indicating a change in the output characteristics when the distance X between the end of the second ITO layer 7, which is a transparent conductive film on the back surface side, and the end portion of the n-type silicon substrate 1 as illustrated in FIG. 1 is changed in the photovoltaic element in the present embodiment. At this point, when X is 0.5 mm or larger, the length in the plane direction of the structure in which the first amorphous silicon i layer 2, the amorphous silicon p layer 4, the second amorphous silicon i layer 3, and the amorphous silicon n layer 5 are laminated, in the order that they appear in this sentence, from the end portion Se of the n-type silicon substrate 1 is fixed at 0.5 mm. When the length of the laminated structure in the plane direction is equal to or smaller than 0.5 mm, this length is indicated by X. At this point, the resistivity of the n-type silicon substrate 1 is 2 Ωcm. In this example, the end portion of the first ITO layer (transparent conductive film) 6 substantially matches the end portion Se of the n-type silicon substrate 1. The second ITO layer 7 is formed such that the end portion thereof is located on the inner side of the end portion of the first ITO layer (transparent conductive film) 6 by the distance X. The distance X means that the transparent conductive film (the second ITO layer 7) is formed to have a smaller area by this distance from the end portion Se of the n-type silicon substrate 1 over the entire periphery. In the photovoltaic element for which the characteristics are evaluated, the n-type silicon substrate 1 is an n-type single-crystal silicon substrate (the substrate resistivity is approximately 2 Ωcm) having a thickness of 100 μm, the amorphous silicon i layers 2 and 3 each have a thickness of 10 nm, and the amorphous silicon p layer 4 and the amorphous silicon n layer 5 have a thickness of approximately 20 nm. As a comparative example, the characteristics of the structure illustrated in FIG. 12 are represented by the curve “b” in FIG. 5. The structure illustrated in FIG. 12 is obtained by depositing the first and second ITO layers 6 and 7, which are transparent conductive films on both the first and second main surfaces, by mask deposition that does not require any additional process. In this comparative example, the first and second ITO layers 6 and 7, which are transparent conductive films on the first main surface 1A and the second main surface 1B, are formed such that they have a smaller area than that of the n-type silicon substrate 1 so as to have a structure that suppress leakage current. In FIG. 5, the distance X is the distance between the end portion Se of the n-type silicon substrate 1 and the end portion of the second ITO layer (transparent conductive film) 7 on the second main surface of the n-type silicon substrate 1.

As is understood from the comparison between the curve “a” and the curve “b” in FIG. 5, when the distance X between the first and second ITO layers (transparent conductive films) 6 and 7 is within a range between approximately 0.1 mm and 3 mm, it is possible to maintain excellent output characteristics compared to those of the photovoltaic element in the comparative example. The distance X is preferably in a range between 0.25 mm and 2.5 mm, and more preferably in a range between 0.5 mm and 2.0 mm. Within such ranges, it is possible to always obtain excellent output characteristics compared to those of the photovoltaic element in the comparative example within the normal design range. Even when the transparent conductive film (the second ITO layer 7) on the second main surface 1B side has a smaller area than that of the substrate, if the second ITO layer 7 does not come into contact with the transparent conductive film (the first ITO layer 6) or a poor junction, the generated carriers can contribute to power generation to some degree without the carriers being eliminated. Therefore, it is thought that, overall, output equal to or higher than that of the photovoltaic element in the comparative example illustrated in FIG. 12 can be obtained.

From the above results, in the present embodiment, on the peripheral portion of the second main surface 1B, the distance in the plane direction between the end portion of the first transparent conductive film and the end portion of the second transparent conductive film is set to be equal to or more than 0.1 mm and equal to or less than 3 mm. Furthermore, on the second main surface 1B, the length in the plane direction of the structure in which the first amorphous silicon i layer 2, the amorphous silicon p layer 4, the second amorphous silicon i layer 3, and the amorphous silicon n layer 5 are laminated, in the order that they appear in this sentence, is set to be equal to or more than 0.1 mm and equal to or less than 3 mm between the first and second ITO layers 6 and 7. Consequently, leakage current is not generated and thus high efficiency can be achieved.

On the peripheral portion of the second main surface 1B, the distance in the plane direction between the end portion of the first transparent conductive film and the end portion of the second transparent conductive film is preferably set to be equal to or more than 0.25 mm and equal to or less than 2.5 mm, and more preferably set to be equal to or more than 0.5 mm and equal to or less than 2.0 mm. Moreover, on the second main surface 1B, the length in the plane direction of the structure in which the first amorphous silicon i layer 2, the amorphous silicon p layer 4, the second amorphous silicon i layer 3, and the amorphous silicon n layer 5 are laminated, in the order that they appear in this sentence, is preferably set to be equal to or more than 0.25 mm and equal to or more than 2.5 mm, and more preferably set to be equal to or more than 0.5 mm and equal to or less than 2.0 mm between the first and second ITOs. With such a structure, further highly efficient characteristics can be obtained.

Moreover, the film thickness of each of the first amorphous silicon i layer 2 and the amorphous silicon p layer 4 that are formed to wrap around onto the peripheral portion of the second main surface 1B becomes in some cases smaller than that when they are formed on the first main surface 1A depending on the deposition conditions; however, when the film thickness of each of the layers formed to wrap around onto the peripheral portion of the second main surface 1B is equal to or more than 50% of the film thickness of each of the layers formed on the first main surface 1A, and the laminated structure of the second amorphous silicon i layer 3 and the amorphous silicon n layer 5 that are arranged over the first amorphous silicon i layer 2 and the amorphous silicon p layer 4 is within a range equal to or more than 0.1 mm and equal to or less than 3 mm from the peripheral portion of the n-type silicon substrate 1, both the leakage current reduction effect and the current collecting effect can be achieved and thus excellent characteristics can be obtained. The film thickness of each of the first amorphous silicon i layer 2 and the amorphous silicon p layer 4 that are formed to wrap around onto the peripheral portion of the second main surface 1B is preferably equal to or more than 80% of the film thickness of each of the layers formed on the first main surface 1A, and the length of the laminated structure is preferably equal to or more than 0.25 mm and equal to or less than 2.5 mm, and more preferably equal to or more than 0.5 mm and equal to or less than 2.0 mm. With such a configuration, leakage current is sufficiently suppressed so that the characteristics are not affected and thus higher output characteristics can be obtained. The film thickness of each of the first amorphous silicon i layer 2 and the amorphous silicon p layer 4 that are formed to wrap around onto the peripheral portion of the second main surface 1B is set to be equal to or more than 50% of the film thickness of each of the layers formed on the first main surface 1A. This is because when the film thickness of each of the layers formed to wrap around onto the peripheral portion of the second main surface 1B is approximately 50% of the film thickness of each of the layers on the first main surface 1A, each layer can substantially exhibit its function. When the film thickness of each of the layers formed to wrap around onto the peripheral portion of the second main surface 1B is equal to or more than approximately 80% of the film thickness of each of the layers on the first main surface 1A, each layer can exhibit its function substantially perfectly.

In the present embodiment, the first amorphous silicon i layer 2, the amorphous silicon p layer 4 having a conductivity type different from that of the n-type silicon substrate 1, the second amorphous silicon i layer 3, and the amorphous silicon n layer 5 having the same conductivity type as that of the n-type silicon substrate 1 are formed; however, the first and second amorphous silicon i layers 2 and 3 may be formed first. In such a case, between the first and second ITO layers 6 and 7, a structure is formed in which the first amorphous silicon i layer 2, the amorphous silicon p layer 4, and the amorphous silicon n layer 5 are laminated in the order that they appear in this sentence. Even with such a configuration, the leakage current flowing between the first ITO layer 6 and the n-type silicon substrate 1 through each amorphous layer can be suppressed.

However, when the amorphous silicon n layer 5 is formed before the amorphous silicon p layer 4 and the amorphous silicon n layer 5 is inserted between the amorphous silicon p layer 4 and the n-type silicon substrate, the configuration becomes such that the p-type amorphous silicon, the n-type amorphous silicon, and the n-type crystalline silicon are formed from above in the order that they appear in this sentence (the intrinsic amorphous silicon layer is ignored) and excellent characteristics cannot be obtained. The reason why excellent characteristics cannot be obtained is that, because a junction having poor characteristics is formed at the pn junction, carriers cannot be efficiently collected.

From the above point, higher characteristics can be obtained by forming the p-type amorphous silicon layer before the n-type semiconductor layer to have a configuration in which the n-type amorphous silicon, the p-type amorphous silicon, and the n-type crystalline silicon are laminated as in the process of the present embodiment. This is because it is desirable to form a pn junction between a substrate and an amorphous silicon layer with respect to the characteristics.

Moreover, in the end portion of the amorphous silicon p layer 4 formed on the second main surface 1B, the thickness is non-uniform; therefore, the diode characteristics easily deteriorate and leakage easily occurs. Therefore, by having a laminated structure of the second amorphous silicon i layer 3, which is in contact with the second main surface 1B of the n-type silicon substrate 1, and the amorphous silicon n layer 5 between the second ITO layer 7 and the laminated structure of the first amorphous silicon i layer 2, the amorphous silicon p layer 4, the second amorphous silicon i layer 3, and the amorphous silicon n layer 5 on the peripheral portion of the second main surface 1B within the design range described above, it is possible to avoid electrical contact with a degraded diode. Consequently, higher characteristics can be obtained.

When the value of the resistivity of the n-type single-crystal silicon substrate 1 is approximately equal to or less than 4 Ωcm, a similar result is obtained. If the resistivity of the n-type single-crystal silicon substrate 1 exceeds 4 Ωcm, the output is reduced because of an increase in the series resistance.

### Second Embodiment

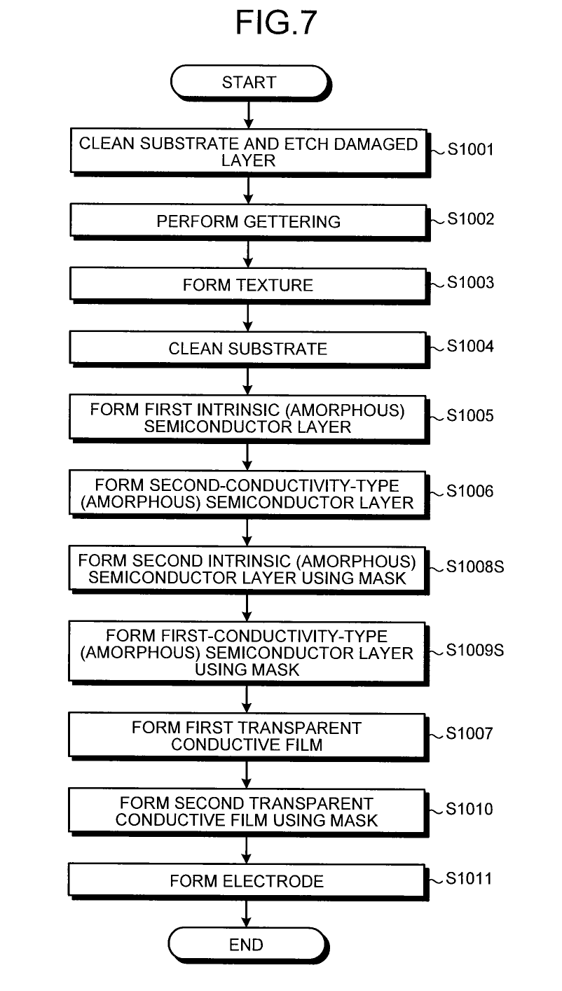

FIG. 6 is a cross-sectional view of the structure of a photovoltaic element according to a second embodiment in the present invention. FIG. 7 is a flowchart illustrating the manufacturing process of the photovoltaic element. The photovoltaic element in FIG. 6 is formed such that when the second amorphous silicon i layer 3 and the amorphous silicon n layer 5 are deposited on the second main surface 1B, a mask is used so as to form the second amorphous silicon i layer 3 and the amorphous silicon n layer 5 with a smaller area than that of the substrate (the n-type silicon substrate 1). Other configurations are the same as those of the photovoltaic element in the first embodiment illustrated in FIG. 1; therefore, explanation thereof is omitted.

As illustrated in the flowchart in FIG. 7, before the process (Step S1007: first transparent conductive film formation) of forming the first ITO layer 6 is performed, the second amorphous silicon i layer 3 and the amorphous silicon n layer 5 are formed on the second main surface 1B side by using a mask (Step S1008S: second intrinsic amorphous semiconductor layer formation using a mask and Step S1009S: first-conductivity-type amorphous semiconductor layer formation using a mask). Other steps are the same as the manufacturing steps for the photovoltaic element in the first embodiment illustrated in FIG. 4; therefore, explanation thereof is omitted.

In the present embodiment, the transparent conductive films (the first and second ITO layers 6 and 7) can be formed after the amorphous silicon n layer 5 is formed. Therefore, metal contamination of the n-type silicon substrate 1 can be reduced compared to the case where the second amorphous silicon i layer 3 is formed after the first ITO layer 6, which is a transparent conductive film on the first main surface 1A side, is formed. Consequently, the characteristics can be improved.

### Third Embodiment

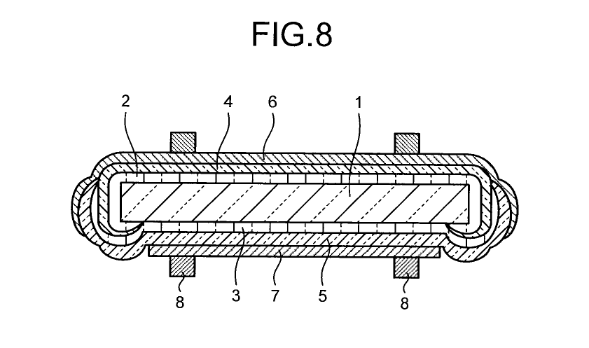

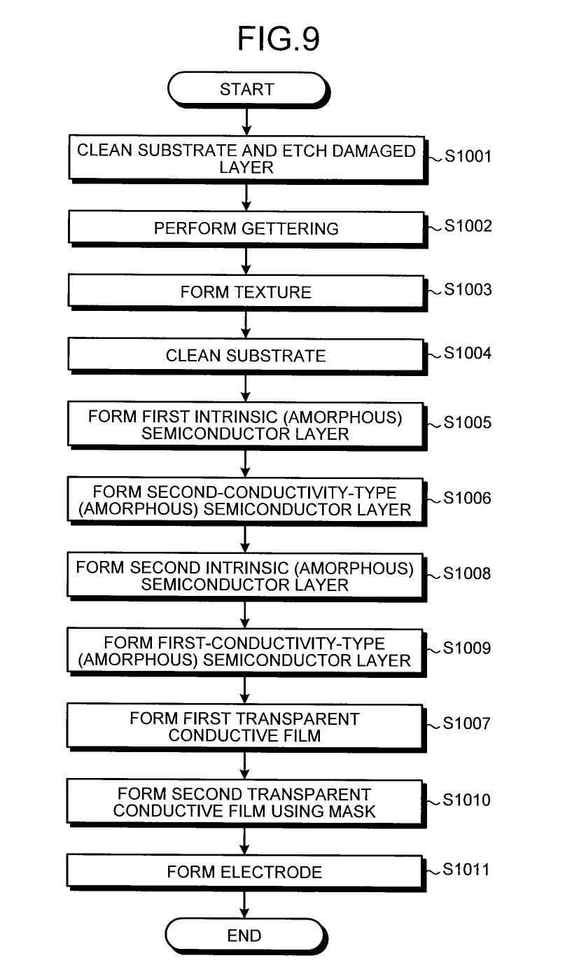

FIG. 8 is a cross-sectional view of the structure of a photovoltaic element according to a third embodiment in the present invention. FIG. 9 is a flowchart illustrating the manufacturing process of the photovoltaic element. The photovoltaic element in FIG. 8 is formed such that the second amorphous silicon i layer 3 and the amorphous silicon n layer 5 are formed on the second main surface 1B before the first ITO layer (transparent conductive film) 6 is formed. Other configurations are the same as those of the photovoltaic element in the first embodiment illustrated in FIG. 1; therefore, explanation thereof is omitted. In the present embodiment, unlike the second embodiment, the second amorphous silicon i layer 3 and the amorphous silicon n layer 5 are formed over the entire second main surface 1B, and in this case, the second amorphous silicon i layer 3 and the amorphous silicon n layer 5 are formed not only over the second main surface 1B but also over the side surfaces 10 and the peripheral portion of the first main surface 1A.

As illustrated in the flowchart in FIG. 9, before the process (Step S1007: first transparent conductive film formation) of forming the first ITO layer 6 is performed, the second amorphous silicon i layer 3 and the amorphous silicon n layer 5 on the second main surface 1B side are formed without using a mask (Step S1008: second intrinsic amorphous semiconductor layer formation and Step S1009: first-conductivity-type amorphous semiconductor layer formation). Other steps are the same as the manufacturing steps for the photovoltaic element in the first embodiment illustrated in FIG. 4; therefore, explanation thereof is omitted.

In the present embodiment, in a similar manner to the second embodiment, the transparent conductive films (the first and second ITO layers 6 and 7) can be formed after the amorphous silicon n layer 5 is formed. Therefore, metal contamination of the n-type silicon substrate 1 can be reduced compared to the case where the second amorphous silicon i layer 3 is formed after the first ITO layer 6, which is a transparent conductive film on the first main surface 1A side, is formed. Consequently, the characteristics can be improved. Moreover, in this case, the second amorphous silicon i layer 3 and the amorphous silicon n layer 5 are formed not only over the second main surface 1B but also over the side surfaces 10 and the peripheral portion of the first main surface 1A. In other words, the entire surface of the n-type silicon substrate 1 is covered with the semiconductor layers before the transparent conductive films (the first and second ITO layers 6 and 7) are formed; therefore, degradation of the characteristics due to metal contamination of the n-type silicon substrate 1 does not occur and it is not necessary to perform mask alignment to form the amorphous silicon n layer 5. Consequently, the characteristics are excellent and productivity is excellent.

The amorphous silicon n layer 5 and the first ITO layer 6 are in contact with each other in the side-surface direction; however, as illustrated in FIG. 5, there is no risk of causing an adverse effect on the characteristics as long as the distance between the end portion of the substrate and the end portion of the transparent conductive film is equal to or more than 0.5 mm.

### Fourth Embodiment

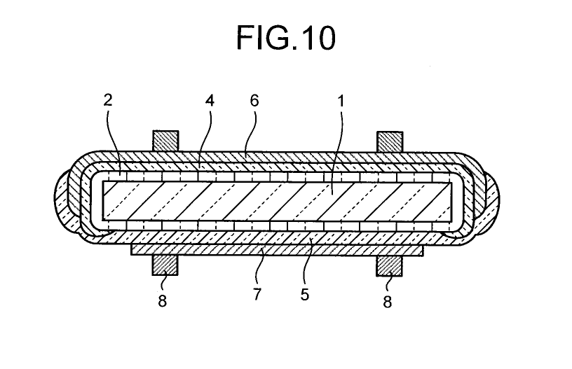

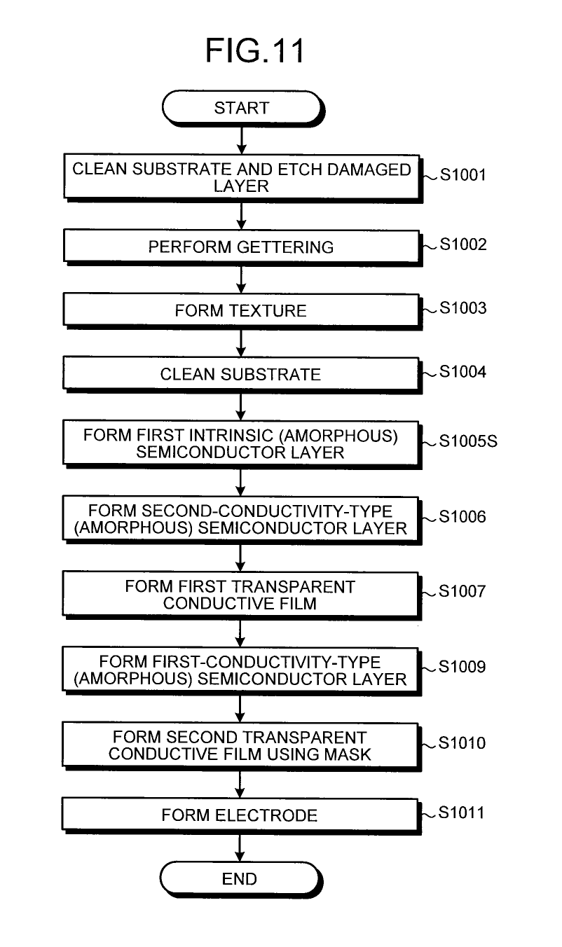

FIG. 10 is a cross-sectional view of the structure of a photovoltaic element according to a fourth embodiment in the present invention. FIG. 11 is a flowchart illustrating the manufacturing process of the photovoltaic element. The photovoltaic element in FIG. 10 is formed such that after the first amorphous silicon i layer 2, which is a substantially intrinsic amorphous silicon layer, is formed over the entire surface of the n-type silicon substrate 1 (Step S1005S), the amorphous silicon p layer 4 (Step S1006), the first ITO layer (transparent conductive film) 6 (Step S1007), the amorphous silicon n layer 5 (Step S1009), and the second ITO layer (transparent conductive film) 7 (Step S1010) are formed in the order that they appear in this sentence, and finally, the metal electrode 8 is formed (Step S1011).

As illustrated in the flowchart in FIG. 11, the process of forming an amorphous silicon i layer over the entire surface of the n-type silicon substrate 1 (S1005S) is performed instead of S1005, which is the first intrinsic semiconductor layer formation step in FIG. 4, and the second intrinsic semiconductor layer formation step S1008 is omitted. Other steps are the same as the manufacturing steps for the photovoltaic element in the first embodiment illustrated in FIG. 4; therefore, explanation thereof is omitted.

In the present embodiment, because the intrinsic amorphous silicon layers are formed over the entire surface of the n-type silicon substrate 1 before the transparent conductive films are formed, there is no problem of metal contamination. Moreover, when the amorphous silicon n layer 5 is formed, a mask is not needed; therefore, contamination due to, for example, attachment and detachment of a mask does not occur. Consequently, the characteristics are excellent and productivity is excellent.

In the present embodiment, in a similar manner to the third embodiment, the amorphous silicon n layer 5 and the first ITO layer 6 are in contact with each other in the side-surface direction; however, as illustrated in FIG. 5, there is no risk of causing an adverse effect on the characteristics as long as the distance between the end portion of the substrate and the end portion of the transparent conductive film is equal to or more than 0.5 mm.

### Fifth Embodiment

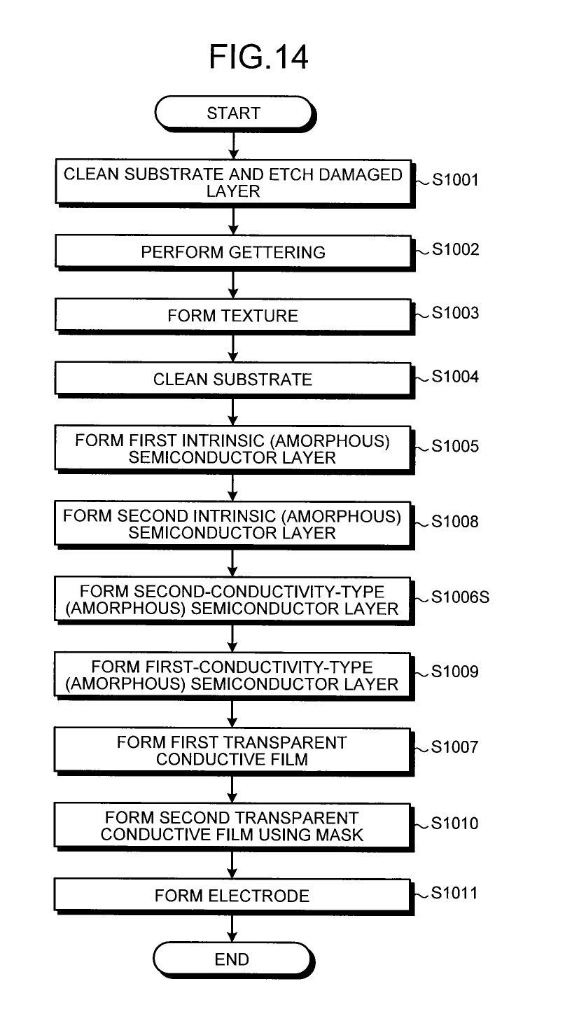

FIG. 13 is a cross-sectional view of the structure of a photovoltaic element according to a fifth embodiment in the present invention. FIG. 14 is a flowchart illustrating the manufacturing process of the photovoltaic element. The photovoltaic element in FIG. 13 is formed such that after the first amorphous silicon i layer 2, which is a substantially intrinsic amorphous silicon layer, is formed on the first main surface 1A, the side surfaces 1C, and the peripheral portion of the second main surface 1B of the n-type silicon substrate 1 (Step S1005), the second amorphous silicon i layer 3 is formed by using a mask (Step S1008). Then, the amorphous silicon p layer 4 is formed (Step S1006S). At this point, a CVD device having a structure illustrated in FIG. 3(a) is used, and by using, as the support 102, a convex structure that has a convex portion having an area that is larger than that used when the first amorphous silicon i layer 2 is formed and is smaller than that of the n-type silicon substrate 1, the desired structure can be manufactured. Thereafter, the amorphous silicon n layer 5 (Step S1009), the first ITO layer 6 (Step S1007), and the second ITO layer 7 (Step S1010) are formed in the order that they appear in this sentence, and finally, the metal electrode 8 is formed (Step S1011). In this case, a laminated structure of the first amorphous silicon i layer 2, the amorphous silicon p layer 4, and the amorphous silicon n layer 5 can be formed between the first ITO layer 6 and the second ITO layer 7.

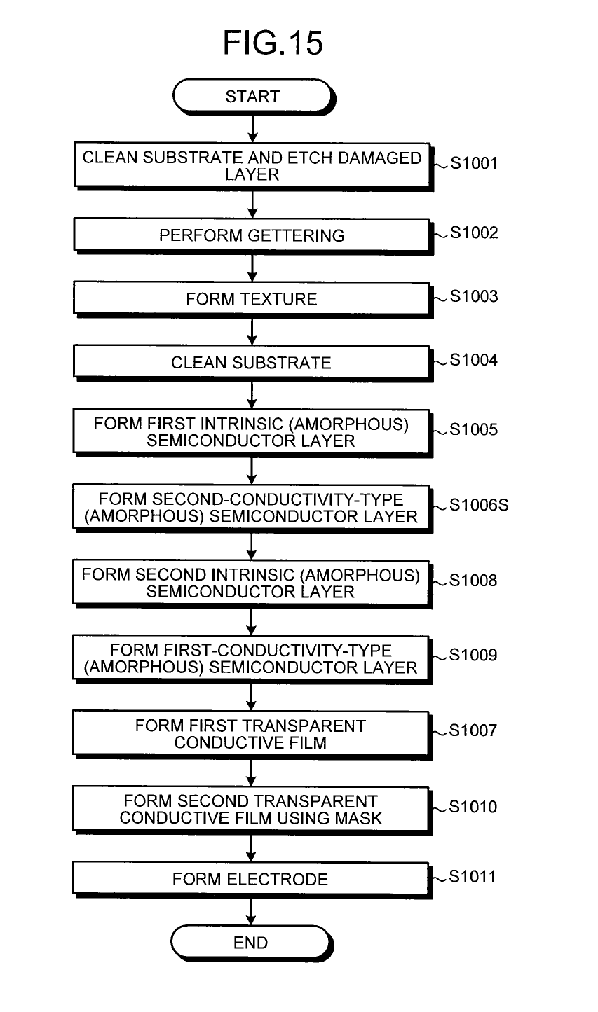

Alternatively, as illustrated in the flowchart in FIG. 15, before the process (Step S1008) of forming the second amorphous silicon i layer 3 is performed, the amorphous silicon p layer 4 may be formed (Step S1006S). At this point, a CVD device having a structure illustrated in FIG. 3(a) is used, and by using, as the support 102, a convex structure that has a convex portion having an area that is larger than that used when the first amorphous silicon i layer 2 is formed and is smaller than that of the n-type silicon substrate 1, the desired structure can be manufactured. Other steps are the same as the manufacturing steps for the photovoltaic element in the first embodiment; therefore, explanation thereof is omitted. In this case, a laminated structure of the first amorphous silicon i layer 2, the amorphous silicon p layer 4, the second amorphous silicon i layer 3, and the amorphous silicon n layer 5 is also formed between the first ITO layer 6 and the second ITO layer 7.

In the present embodiment, because the intrinsic amorphous silicon is formed over the entire surface of the n-type silicon substrate 1 before the transparent conductive films are formed, there is no problem of metal contamination. Moreover, on the peripheral portion of the second main surface 1B, a region is formed in which the first amorphous silicon i layer 2 and the second amorphous silicon i layer 3 overlap with each other; therefore, a substantially thick intrinsic amorphous silicon layer can be formed. At this point, if the length of the region of the substantially thick intrinsic amorphous silicon layer in a direction toward the center of the semiconductor substrate is equal to or more than 0.05 mm, it is possible to suppress leakage current flowing between the first ITO layer 6 and the n-type silicon substrate 1 through each amorphous layer. If the length of the region of the substantially thick intrinsic amorphous silicon layer in a direction toward the center of the semiconductor substrate is less than 0.05 mm, it is difficult to suppress leakage current by the intrinsic amorphous silicon layer structure formed to have a substantially large thickness. On the other hand, because the length of the region of the laminated structure of the amorphous silicon p layer 4 and the amorphous silicon n layer 5 in a direction toward the center of the semiconductor substrate needs to be at least 0.1 mm, if the length exceeds 2.9 mm, the electric field applied to the metal electrode 8 cannot be sufficiently applied to the junction formed between the amorphous silicon p layer 4 and the amorphous silicon n layer 5 and thus it becomes difficult to maintain the current collecting effect. Therefore, when the length of the region of the intrinsic amorphous silicon layer in a direction toward the center of the semiconductor substrate is in a range equal to or more than 0.05 mm and equal to or less than 2.9 mm, leakage current can be suppressed and the current collecting effect can be maintained; therefore, the characteristics are excellent.

The length of the region of the substantially thick intrinsic amorphous silicon layer in a direction toward the center of the semiconductor substrate is preferably in a range equal to or more than 0.1 mm and equal to or less than 2.4 mm, and more preferably in a range equal to or more than 0.1 mm and equal to or less than 1.9 mm. Within such ranges, leakage current can be further suppressed and the current collecting efficiency is increased; therefore, high characteristics can be obtained.

In the present embodiment, in a similar manner to the third embodiment, the amorphous silicon n layer 5 and the first ITO layer 6 are in contact with each other in the side-surface direction; however, as illustrated in FIG. 5, there is no risk of causing an adverse effect on the characteristics as long as the distance between the end portion of the substrate and the end portion of the transparent conductive film is equal to or more than 0.5 mm.

In the plasma CVD device used in the first to fifth embodiments, a support is used that has a convex portion having a smaller area than that of the semiconductor substrate. The first main surface or the second main surface of the semiconductor substrate is brought into contact with the convex portion and films are formed such that they cover the entire first or second main surface and extend to a predetermined width of the peripheral portion of the second or first main surface by wrapping around the side surfaces. When each film is formed, it is possible to adjust the wrap-around distance with high accuracy by adjusting the size of the convex portion. It is desirable that the wrap-around distance is uniform. However, the structure may be deviated. For example, the semiconductor layers located between the end portions of the first and second transparent conductive films may be configured such that only a part thereof has a pipn structure and other parts have a pin structure.

Moreover, the transparent conductive films are not limited to ITOs and can be appropriately changed to tin oxide, zinc oxide, or the like.

As the semiconductor substrate, other than a crystalline silicon substrate, such as a single-crystal silicon substrate and a polycrystalline silicon substrate, for example, a crystalline silicon-based substrate, examples of which include a silicon compound substrate, such as a silicon carbide substrate, can also be used. As the intrinsic amorphous silicon thin film or the amorphous silicon thin film having each conductivity type, a crystalline thin film, such as a microcrystalline silicon-based thin film and a polycrystalline silicon-based thin film, can also be used.

### INDUSTRIAL APPLICABILITY

As described above, the photovoltaic element and the manufacturing method thereof according to the present invention can shorten the manufacturing time because a complex additional process is not necessary and can maximize the effective area of the substrate while preventing leakage current, and are thus useful for improving the conversion efficiency. In particular, the photovoltaic element and the manufacturing method thereof according to the present invention are suitable for photovoltaic power generation.

### REFERENCE SIGNS LIST

1 n-type silicon substrate, 2 first amorphous silicon i layer, 3 second amorphous silicon i layer, 4 amorphous silicon p layer, 5 amorphous silicon n layer, 6 first ITO layer, 7 second ITO layer, 8 metal electrode, 100 plasma CVD device, 101 processing chamber, 102, 102S support (anode electrode), 103 cathode electrode, 104 gas supply portion, 105 discharge portion, 106 high-frequency (RF) power supply, Se end portion, S0 normal line S0 extending from the end portion of the second ITO layer 7 toward the surface of the n-type silicon substrate 1.

1. A photovoltaic element comprising:
a first-conductivity-type semiconductor substrate that includes a first main surface, a side surface, and a second main surface;
a second-conductivity-type semiconductor layer that is formed such that the second-conductivity-type semiconductor layer entirely covers the first main surface of the semiconductor substrate and covers a peripheral portion of the second main surface by wrapping around the side surface from the first main surface;
a first intrinsic semiconductor layer that is interposed between the second-conductivity-type semiconductor layer and the semiconductor substrate;
a first transparent conductive film that is formed such that the first transparent conductive film is in contact with the second-conductivity-type semiconductor layer and extends to the side surface from the first main surface;
a first-conductivity-type semiconductor layer that is formed over the second main surface of the semiconductor substrate;
a second intrinsic semiconductor layer that is interposed between the first-conductivity-type semiconductor layer and the semiconductor substrate; and
a second transparent conductive film that is provided on a side of the second main surface of the semiconductor substrate such that the second transparent conductive film is in contact with the first-conductivity-type semiconductor layer, wherein
the second transparent conductive film is formed such that an end portion is located on an inner side of an outer edge of the second main surface of the semiconductor substrate, and
is formed such that the second transparent conductive film does not intersect with the first transparent conductive film along a normal line that extends from the end portion of the second transparent conductive film toward the second main surface, and
on the second main surface, in a region that is located between an end portion of the first transparent conductive film and the end portion of the second transparent conductive film, at least one of a structure, in which the first intrinsic semiconductor layer, the second-conductivity-type semiconductor layer, the second intrinsic semiconductor layer, and the first-conductivity-type semiconductor layer are laminated in order, and a structure, in which the first intrinsic semiconductor layer, the second-conductivity-type semiconductor layer, and the first-conductivity-type semiconductor layer are laminated in order, is provided.

2. The photovoltaic element according to claim 1, wherein
on the peripheral portion of the second main surface of the semiconductor substrate, between the end portion of the first transparent conductive film and the end portion of the second transparent conductive film, a region of the structure, in which the first intrinsic semiconductor layer, the second-conductivity-type semiconductor layer, the second intrinsic semiconductor layer, and the first-conductivity-type semiconductor layer are laminated in order, or the structure, in which the first intrinsic semiconductor layer, the second-conductivity-type semiconductor layer, and the first-conductivity-type semiconductor layer are laminated in order, has a length equal to or more than 0.1 mm and equal to or less than 3 mm in a direction from an end portion toward a center of the semiconductor substrate on the second main surface, and
a distance between the end portion of the first transparent conductive film and the end portion of the second transparent conductive film is equal to or more than 0.1 mm and equal to or less than 3 mm.

3. The photovoltaic element according to claim 1, wherein the first-conductivity-type semiconductor layer is arranged over the second-conductivity-type semiconductor layer.

4. The photovoltaic element according to claim 1, wherein on the side surface of the semiconductor substrate, the first transparent conductive film is in contact with the second-conductivity-type semiconductor layer and is arranged on a laminate of the second intrinsic semiconductor layer and the first-conductivity-type semiconductor layer.

5. The photovoltaic element according to claim 1, wherein the first intrinsic semiconductor layer and the second-conductivity-type semiconductor layer are formed up to the peripheral portion of the second main surface of the semiconductor substrate, and on the peripheral portion, the second intrinsic semiconductor layer that is in contact with the second main surface of the semiconductor substrate and the first-conductivity-type semiconductor layer are provided between the second transparent conductive film and the first intrinsic semiconductor layer, the second-conductivity-type semiconductor layer, the second intrinsic semiconductor layer, and the first-conductivity-type semiconductor layer that are laminated.

6. The photovoltaic element according to claim 1, wherein the second-conductivity-type semiconductor layer and the first intrinsic semiconductor layer are maintained at a film thickness equal to or more than 50% of a film thickness on the first main surface, and wrap around onto a periphery of the second main surface from the side surface of the semiconductor substrate by a distance equal to or more than 0.1 mm and equal to or less than 3 mm from the end portion of the second main surface.

7. The photovoltaic element according to claim 1, wherein
the semiconductor substrate is a crystalline silicon substrate, and
the first-conductivity-type and second-conductivity-type semiconductor layers and the first and second intrinsic semiconductor layers are an amorphous or microcrystalline silicon-based thin film layer.

8. The photovoltaic element according to claim 1, wherein a structure, in which the first intrinsic semiconductor layer and the second intrinsic semiconductor layer are formed in an overlapping manner, is provided on the peripheral portion of the second main surface and between the end portion of the first transparent conductive film and the end portion of the second transparent conductive film.

9. The photovoltaic element according to claim 8, wherein on the peripheral portion of the second main surface, a region, in which the second intrinsic semiconductor layer is formed so as to overlap with the first intrinsic semiconductor layer, has a length equal to or more than 0.1 mm in a direction toward a center of the second main surface.

10. A manufacturing method of a photovoltaic element comprising, on a first-conductivity-type semiconductor substrate that includes a first main surface, a side surface, and a second main surface:
forming a second-conductivity-type semiconductor layer such that the second-conductivity-type semiconductor layer entirely covers the first main surface of the semiconductor substrate and extends onto a peripheral portion of the second main surface by wrapping around the side surface, with the first intrinsic semiconductor layer therebetween;
forming a first transparent conductive film that is in contact with the second-conductivity-type semiconductor layer and extends to the side surface from the first main surface;
forming a first-conductivity-type semiconductor layer on the second main surface with a second intrinsic semiconductor layer therebetween over at least the second main surface of the semiconductor substrate; and
forming a second transparent conductive film that is in contact with the first-conductivity-type semiconductor layer on a side of the second main surface of the semiconductor substrate, wherein
the second transparent conductive film is formed such that an end portion is located on an inner side of an outer edge of the second main surface of the semiconductor substrate,
the second transparent conductive film is formed such that the second transparent conductive film does not intersect with the first transparent conductive film along a normal line that extends from the end portion of the second transparent conductive film toward the second main surface, and
on the second main surface, in a region that is located between an end portion of the first transparent conductive film and the end portion of the second transparent conductive film, either a structure, in which the first intrinsic semiconductor layer, the second-conductivity-type semiconductor layer, the second intrinsic semiconductor layer, and the first-conductivity-type semiconductor layer are laminated in order, or a structure, in which the first intrinsic semiconductor layer, the second-conductivity-type semiconductor layer, and the first-conductivity-type semiconductor layer are laminated in order, is provided.

11. The manufacturing method of a photovoltaic element according to claim 10,
each of the forming the second-conductivity-type semiconductor layer, the forming the first transparent conductive film, the forming the first-conductivity-type semiconductor layer, and the forming the second transparent conductive film includes using a support that has a convex portion having a smaller area than an area of the semiconductor substrate,
each of the forming the second-conductivity-type semiconductor layer, the forming the first transparent conductive film, the forming the first-conductivity-type semiconductor layer, and the forming the second transparent conductive film includes bringing a side of the first main surface or a side of the second main surface of the semiconductor substrate into contact with the convex portion of the support, and adjusting a distance with which each of the layers entirely covers the first or second main surface and extends onto the peripheral portion on a side of the second or first main surface by wrapping around the side surface.

12. The manufacturing method of a photovoltaic element according to claim 11, wherein the forming the second-conductivity-type semiconductor layer includes using a support that has a convex portion having an area that is larger than when the first intrinsic semiconductor layer is formed and is smaller than an area of the semiconductor substrate, bringing the second main surface of the semiconductor substrate into contact with the convex portion, and forming the second-conductivity-type semiconductor layer such that the second-conductivity-type semiconductor layer entirely covers the first main surface and extends onto the peripheral portion of the second main surface by wrapping around the side surface.

13. The manufacturing method of a photovoltaic element according to claim 10, wherein the forming the first transparent conductive film is performed after forming the first and second intrinsic semiconductor layers.

14. The manufacturing method of a photovoltaic element according to claim 10, wherein the first intrinsic semiconductor layer and the second intrinsic semiconductor layer are formed in an overlapping manner on the peripheral portion of the second main surface and between the end portion of the first transparent conductive film and the end portion of the second transparent conductive film.

15. The manufacturing method of a photovoltaic element according to claim 10, wherein
the semiconductor substrate is a crystalline silicon substrate, and
the first-conductivity-type and second-conductivity-type semiconductor layers and the first and second intrinsic semiconductor layers are an amorphous or microcrystalline silicon-based thin film layer.
